(19) United States
(12) Patent Application Publication
(10) Pub. No.: US 2024/0237259 A9
(43) Pub. Date: Jul. 11, 2024

(54) LOCKING MECHANISM, ELECTRONIC DEVICE STRUCTURE AND SERVER

(71) Applicant: Fulian Precision Electronics (Tianjin) Co., LTD., Tianjin (CN)

(72) Inventor: KE-CHENG LIN, New Taipei (TW)

(21) Appl. No.: 18/211,636

(22) Filed: Jun. 20, 2023

(30) Foreign Application Priority Data
Oct. 20, 2022 (CN) 202211288493.4

(51) Int. Cl. H05K 7/14

(52) U.S. Cl. CPC H05K 7/1489

(57) ABSTRACT

A locking mechanism for mounting hard drive to rack includes a shell and a lock component. The lock component comprises a handle, a pin, a lever, a torsion spring, and a compression spring. When the handle is located on the inner position, the lever latches the handle, the torsion spring is compressed, the compression spring pushes the pin out of the shell to insert into a slot of the rack to lock the hard drive to the rack. When pressing the lever to unlatch the handle, the torsion spring pushes the handle rotate to the outer position, meanwhile the handle retracts the pin into the shell to unlock the hard drive from the rack. An electronic device structure and a server using the locking mechanism is also disclosed.

### FIELD

The subject matter herein generally relates to mounting of hard drive to rack, and to a locking mechanism, an electronic device structure and a server.

### BACKGROUND

Hard drives are usually mounted in a rack for using, so the quick installation and removal of the hard drives are very important to the quality and the efficiency of operation and maintenance, but the structure in present results in low efficiency of mounting.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a locking mechanism according to an embodiment of the present disclosure.

FIG. 2 is an exploded view of the locking mechanism of FIG. 1.

FIG. 3 is an isometric view of the pin of FIG. 2.

FIG. 4 is an isometric view of the handle of FIG. 2.

FIG. 5 is an isometric view of an electronic device structure according to an embodiment of the present disclosure.

FIG. 6 is another isometric view of an electronic device structure of FIG. 5.

FIG. 7 is an isometric view of a server according to an embodiment of the present disclosure.

FIG. 8 is an isometric view of a rack of FIG. 7.

FIG. 9 is a section view of the locking mechanism of FIG. 1 when a handle is on an inner position.

FIG. 10 is a section view of the locking mechanism of FIG. 1 when the handle is on the inner position and a rack presses a pin.

FIG. 11 is a section view of the locking mechanism of FIG. 1 when the handle is on the inner position and the pin is in a slot of the rack.

FIG. 12 is a section view of the locking mechanism of FIG. 1 when the handle is on an outer position.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to”; it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

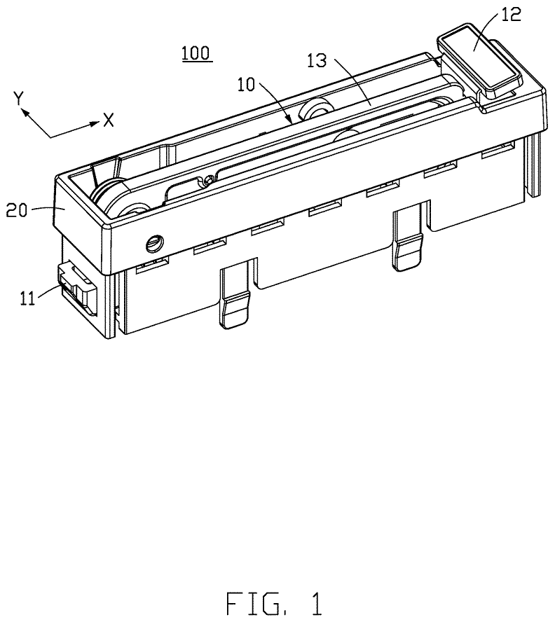

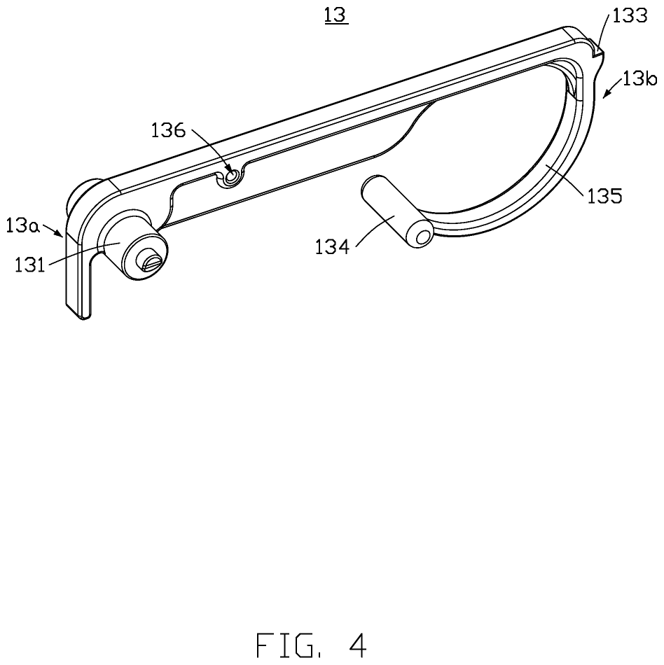

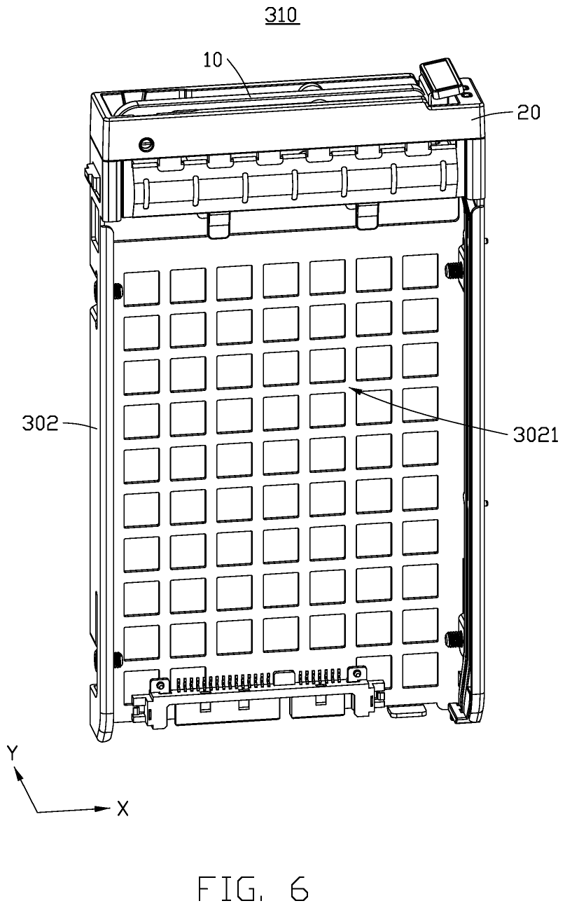

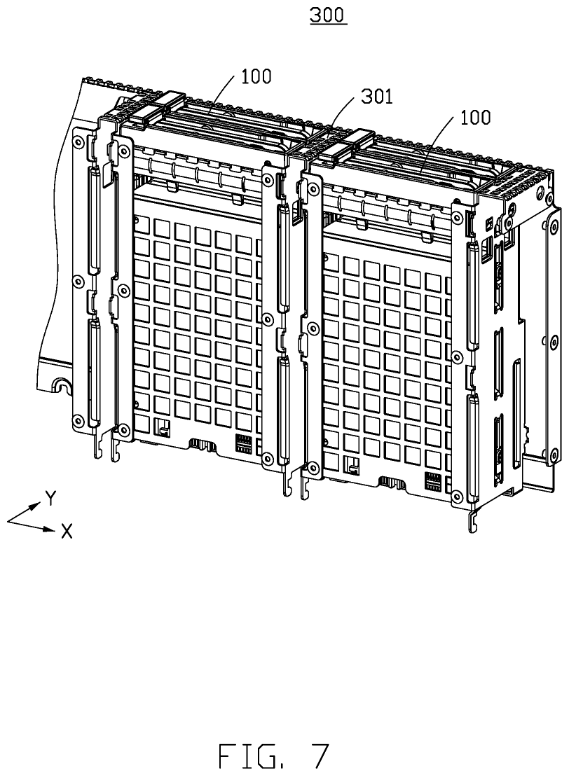

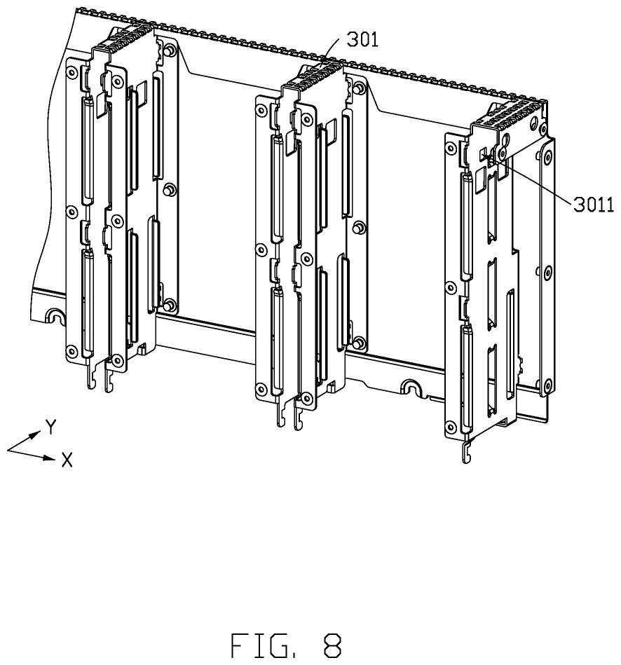

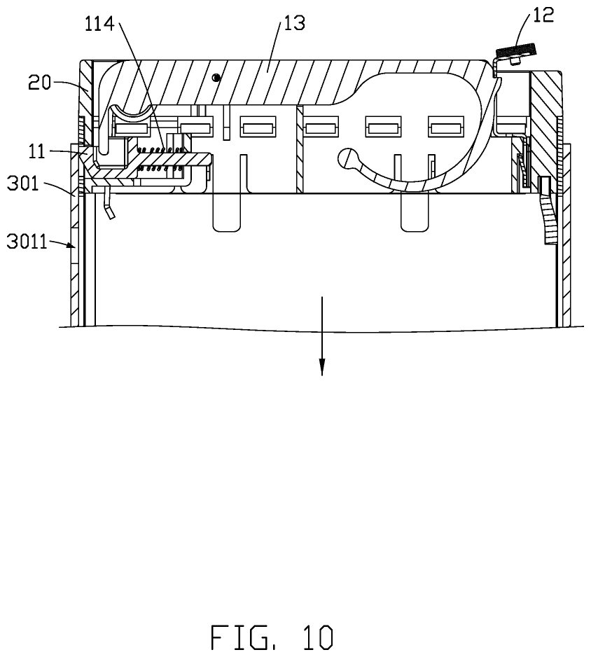

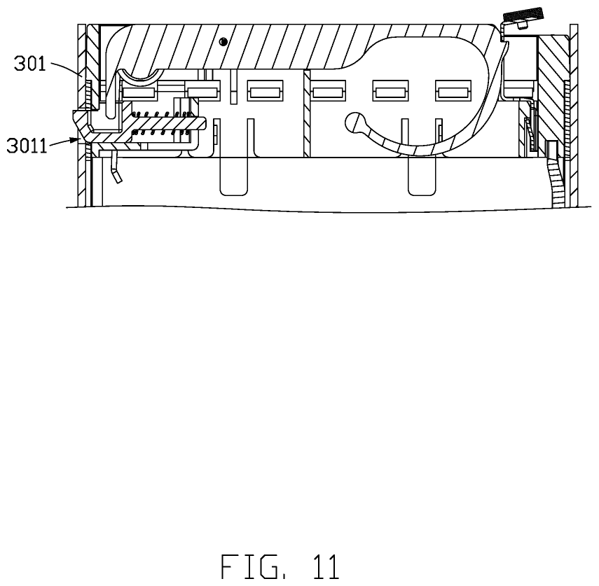

As shown in FIG. 1 to FIG. 12, a lock mechanism 100 in one embodiment is mounted on a storage module 303, the lock mechanism 100 is configured for mounting the storage module 303 to a rack 301 of a server 300. The storage module 303 could be hard drive.

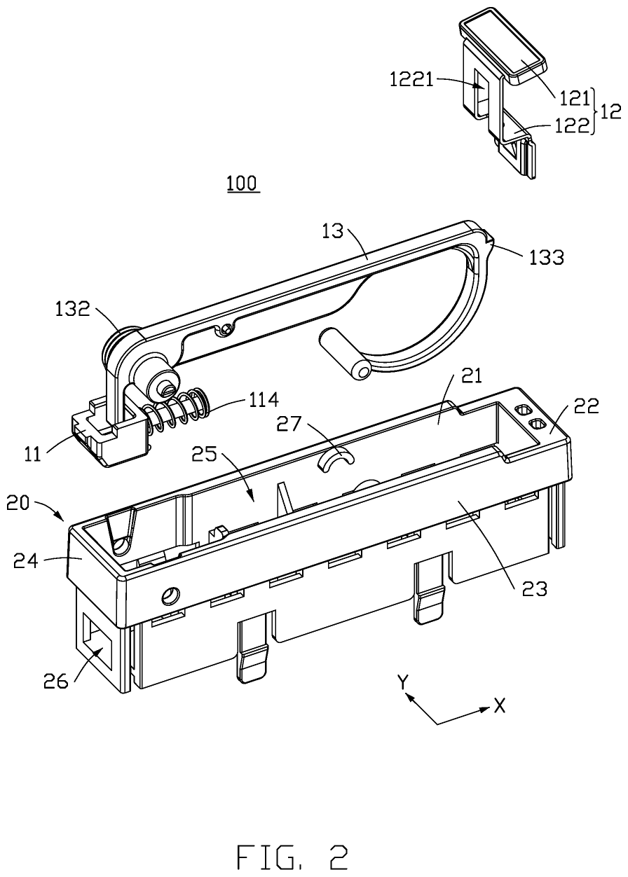

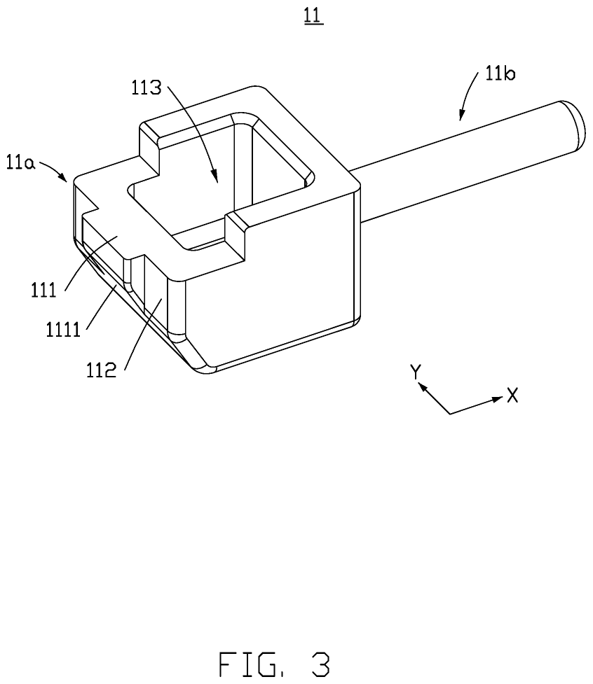

As shown in FIG. 2 and FIG. 3, the lock mechanism 100 includes a shell 20 and a lock component 10. The lock component 10 includes a handle 13, a pin 11, and a lever 12. The handle 13 has a first end 13a and a second end 13b on opposite side. The pin 11 is movably connected to the shell 20, and the pin 11 can extend out of the shell 20 or retract into the shell 20. The handle 13 is rotatably connected to the shell 20 and the handle 13 rotates between an inner position and an outer position relative to the shell. The lever 12 can latch the second end 13b of the handle 13 to hold the handle 13 on the inner position.

The handle 13 is rotatably connected to the shell 20 by an axis 131, a torsion spring 132 is located on the axis 131, the torsion spring 132 is configured for rotating the handle 13 out of the shell 20 to the outer position when lever 12 unlatches the handle 13.

A compression spring 114 is connected between the pin 11 and the shell 20.

The compression spring 114 is configured for pushing the pin 11 to extend out of the shell 20. The shell 20 has a hole 26, and the pin 11 extends out of the shell 20 through the hole 26.

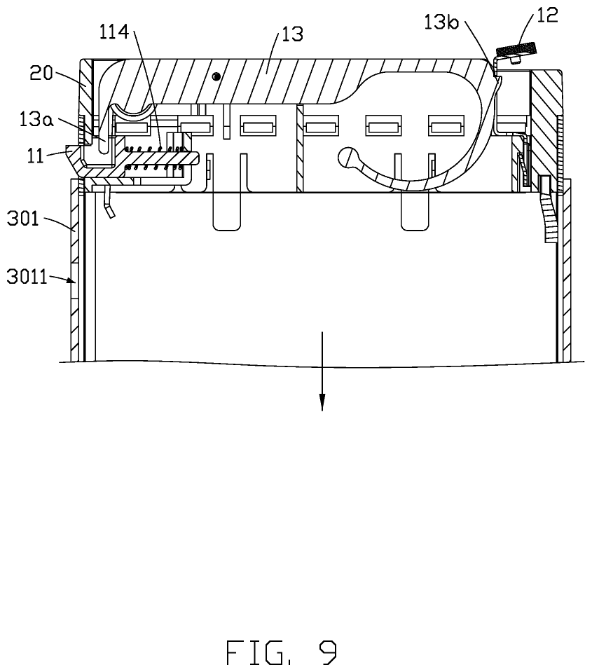

As shown in FIG. 9, when operator put the handle 13 to the inner position, the lever 12 latches the second end 13b of the handle 13, and the compression spring 114 pushes the pin 11 to extend out of the shell 20.

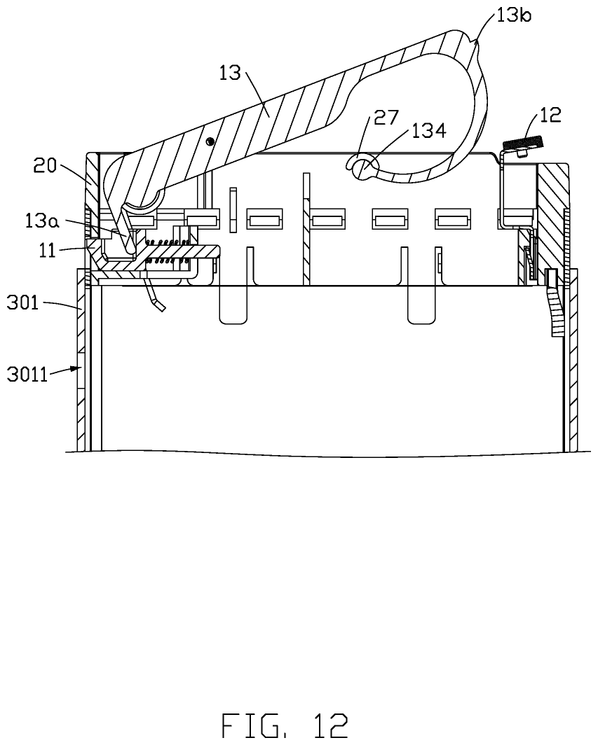

As shown in FIG. 12, when operator press the lever 12 to unlatch the handle 13, the torsion spring 132 drive the handle 13 rotate to the outer position for handling. During the rotation of the handle 13, the first end 13a of the handle 13, in the meantime, pushes the pin 11 to retract back into the shell 20, and meanwhile the compression spring 114 is compressed.

The handle 13 has a first block 134, and the shell 20 has a second block 27. When pressing the lever 12 to unlatch the handle 13 and when the handle 13 rotates to the outer position, the second block 27 can block the first block 134, to limit the angle of rotation of the handle 13.

As shown in FIG. 9 to FIG. 12, the rack 301 of the server 300 has a slot 3011, during the mounting of the storage module 303 to the rack 301, when the pin 11 meets the slot 3011, the compression spring 114 pushes the pin 11 into the slot 3011, to fix the storage module 303 to the rack 301. When to pull out the storage module 303 from the rack 301, operator presses the lever 12 to unlatch the handle 13, the torsion spring 132 drives the handle 13 to the outer position for griping, meanwhile the first end 13a of the handle 13 retracts the pin 11 back into to the shell 20, so the pin 11 get out of the slot 3011, to allow the storage module 303 be removed from the rack 301.

The pin 11 has a third end 11a and a fourth end 11b, and the third end 11a and the fourth end 11b are on the opposite sides of the pin 11. The fourth end 11b is cylinder and is used for fixing the compression spring 114. The third end 11a of the pin 11 has a first latching part 111. As shown in FIG. 9 to FIG. 11, the first latching part 111 has a bevel 1111. During the storage module 303 being inserted into the rack 301, even if the pin 11 extends out of the shell 20, the rack 301 can also moves along the bevel 1111 to press the pin 11 into the shell 20, so to allow the storage module 303 to be mounted to the rack 301.

As shown in FIG. 3, the first latching part 111 further has a step 112, the step 112 protrudes along a direction X from the lock mechanism 100, the height of the step 112 is greater than the distance of the gap between the shell 20 and the rack 301, when the lock mechanism 100 is mounted on the rack 301, the step 112 fill the gap between the lock mechanism 100 and the rack 301, improving the stability.

In summary, no matter which position (the inner position or the outer position) the handle 13 is on, the storage module 303 with the lock mechanism 100 can always be mounted on the rack 301. Especially, when the handle 13 is on the outer position, the storage module 303 can still be inserted into the rack 301, and operator can put the handle 13 back to the inner position after the mounting of the storage module 303 to the rack 301. The handle 13 on the outer position is only for grasping the storage module 303 easier, after the storage module 303 is mounted on the rack 301, the handle 13 shall be set on the inner position.

As shown in FIG. 2, the shell 20 includes a first wall 21, a second wall 22, a third wall 23, and a fourth wall 24, the first wall 21 and the third wall 23 extend along the direction X and arrange along a direction Y, the second wall 22 and the fourth wall 24 extend along the direction Y and arrange along the direction X, the first wall 21, the second wall 22, the third wall 23, and the fourth wall 24 form a first storage space 25. When the handle 13 is on the inner position, the handle 13 is held in the first storage space 25.

As shown in FIG. 3, the pin 11 has a groove 113, the first end 13a of the handle 13 is inserted into the groove 113 and is movable in the groove 113. When the handle 13 rotates to the outer position, the first end 13a in the groove 113 retracts the pin 11 into the shell 20, and when the handle 13 rotates to the inner position, the first end 13a in the groove 113 and the pin 11 are not in contact.

In some embodiments, the lever 12 includes a metal dome 122, the metal dome 122 has a slot 1221, the second end 13b of the handle 13 has a second block 133, the slot 1221 is used for latching the second block 133, to fix the handle 13 on the inner position.

In some embodiments, the lever 12 further includes a button 121, the button 121 is connected to the metal dome 122, and the button 121 is located outside the first storage space 25. When pressing the button 121, the metal dome 122 bends to unlatch the handle 13.

In some embodiments, the handle 13 has a hole 136, the end of the torsion spring 132 is mounted in the hole 136.

In some embodiments, the handle 13 has a pull ring 135, the pull ring 135 is used for grasping the handle 13 easy.

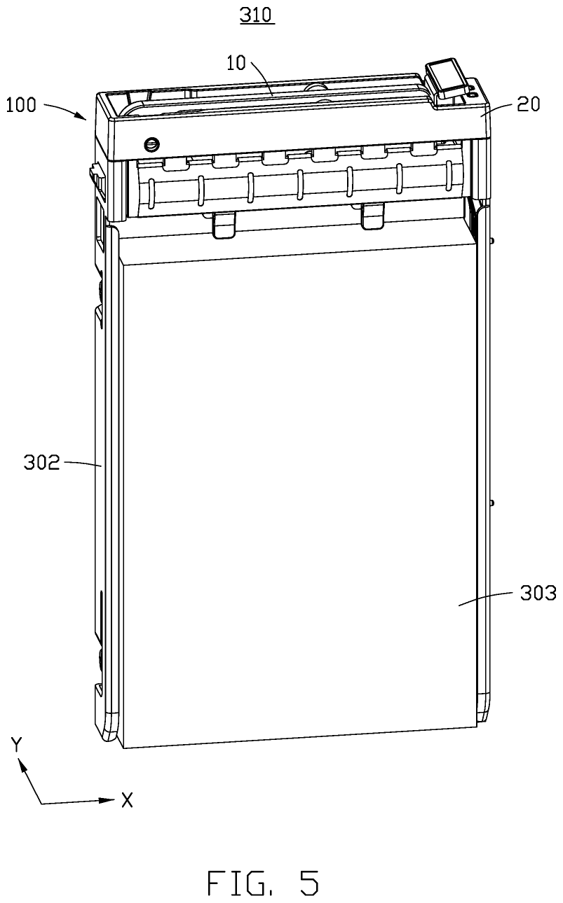

As shown in FIG. 5 to FIG. 7, an electronic device structure 310 in one embodiment includes the rack 301, a bracket 302 and the lock mechanism 100. The lock mechanism 100 is connected to the bracket 302. The bracket 302 is connected to the shell 20. The rack 301 has a slot 3011, when the bracket 302 is mounted to the rack 301, the first latching part 111 inserts into the slot 3011.

As shown in FIG. 5 to FIG. 7, a server 300 in one embodiment includes the storage module 303 and the electronic device structure 310, the storage module 303 is mounted on the bracket 302, the bracket 302 has a second storage space 3021, the second storage space 3021 is used for holding the storage module 303.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A locking mechanism configured for mounting a hard drive to a rack, the locking mechanism comprising:
a shell connected to the hard drive; and
a lock component connected to the shell,
wherein the lock component comprises a handle, a pin, a lever, a torsion spring, and a compression spring, the handle is rotatably connected to the shell and the handle rotates between an inner position and an outer position relative to the shell, the lever is configured for latching the handle, the pin is movably connected to the shell and the pin extends out of the shell or retracts into the shell,
when the handle is located on the inner position, the lever latches the handle, the torsion spring is compressed, the compression spring pushes the pin out of the shell, the pin is configured for inserting into a slot of the rack to lock the hard drive to the rack, and
when pressing the lever to unlatch the handle, the torsion spring pushes the handle rotate to the outer position, meanwhile the handle retracts the pin into the shell to unlock the hard drive from the rack, and the compression spring is compressed.

2. The locking mechanism of claim 1, wherein
the pin comprises a bevel, when the handle is located on the inner position, the bevel extends out of the shell, during the mounting of the hard drive to the rack, the rack moves along the bevel to press the pin into the shell, until the pin meets the slot of the rack, the compression spring pushes the pin out of the shell and into the slot, to lock the hard drive to the rack.

3. The locking mechanism of claim 1, wherein
the pin defines a groove, the handle defines a first end and a second end, the first end is inserted into the groove, the second end is configured for being latched by the lever, when the handle rotates to the outer position, the first end in the groove retracts the pin into the shell, and when the handle rotates to the inner position, the first end in the groove and the pin are not in contact.

4. The locking mechanism of claim 1, wherein
the handle comprises a first block, the shell comprises a second block, and when the handle rotates to the outer position, the second block is configured for blocking the first block to limit an angle of rotation of the handle.

5. The locking mechanism of claim 2, wherein
the pin comprises a third end and a fourth end, the bevel is located on the third end, the fourth end is cylinder, and the compression spring is located on the cylinder.

6. The locking mechanism of claim 5, wherein
the third end of the pin further comprises a step, the step protrudes from the third end, and a height of the step is greater than a distance of the gap between the shell and the rack.

7. The locking mechanism of claim 1, wherein
the shell comprises a first wall, a second wall, a third wall, and a fourth wall, the first wall, the second wall, the third wall, and the fourth wall form a first storage space, and the first storage space is configured for holding the handle on the inner position.

8. The locking mechanism of claim 3, wherein
the level comprises a metal dome and a button, the metal dome is connected to the shell, the metal dome defines a slot, the slot is configured for latching the handle, the button is connected to the metal dome, and the metal dome bends to unlatch the handle by pressing the button.

9. The locking mechanism of claim 1, wherein
the handle comprises a pull ring, when the handle is located on the outer position, the pull ring is located outside of the shell for handling.

10. An electronic device structure comprising:
a rack comprising a slot;
a bracket configured for holding a hard drive; and
a locking mechanism connected to the bracket,
wherein the locking mechanism comprises:
a shell connected to the bracket, and
a lock component connected to the shell,
the lock component comprises a handle, a pin, a lever, a torsion spring, and a compression spring, the handle is rotatably connected to the shell and the handle rotates between an inner position and an outer position relative to the shell, the lever is configured for latching the handle, the pin is movably connected to the shell and the pin extends out of the shell or retracts into the shell,
when the handle is located on the inner position, the lever latches the handle, the torsion spring is compressed, the compression spring pushes the pin out of the shell, the pin is configured for inserting into the slot of the rack to lock the bracket to the rack, and
when pressing the lever to unlatch the handle, the torsion spring pushes the handle rotate to the outer position, meanwhile the handle retracts the pin into the shell to unlock the bracket from the rack, and the compression spring is compressed.

11. The electronic device structure of claim 10, wherein
the pin comprises a bevel, when the handle is located on the inner position, the bevel extends out of the shell, during the mounting of the hard drive to the rack, the rack moves along the bevel to press the pin into the shell, until the pin meets the slot of the rack, the compression spring pushes the pin out of the shell and into the slot, to lock the hard drive to the rack.

12. The electronic device structure of claim 10, wherein
the pin defines a groove, the handle defines a first end and a second end, the first end is inserted into the groove, the second end is configured for being latched by the lever, when the handle rotates to the outer position, the first end in the groove retracts the pin into the shell, and when the handle rotates to the inner position, the first end in the groove and the pin are not in contact.

13. The electronic device structure of claim 10, wherein
the handle comprises a first block, the shell comprises a second block, when the handle rotates to the outer position, the second block is configured for blocking the first block to limit an angle of rotation of the handle.

14. The electronic device structure of claim 11, wherein
the pin comprises a third end and a fourth end, the bevel is located on the third end, the fourth end is cylinder, the compression spring is located on the cylinder.

15. The electronic device structure of claim 14, wherein
the third end of the pin further comprises a step, the step protrudes from the third end, and a height of the step is greater than a distance of the gap between the shell and the rack.

16. The electronic device structure of claim 10, wherein
the shell comprises a first wall, a second wall, a third wall, and a fourth wall, the first wall, the second wall, the third wall, and the fourth wall form a first storage space, and the first storage space is configured for holding the handle on the inner position.

17. The electronic device structure of claim 12, wherein
the level comprises a metal dome and a button, the metal dome is connected to the shell, the metal dome defines a slot, the slot is configured for latching the handle, the button is connected to the metal dome, and the metal dome bends to unlatch the handle by pressing the button.

18. The electronic device structure of claim 10, wherein
the handle comprises a pull ring, when the handle is located on the outer position, the pull ring is located outside of the shell for handling.

19. A server comprising:
a hard drive; and
an electronic device structure comprising:
a rack comprising a slot,
a bracket configured for holding the hard drive, and
a locking mechanism connected to the bracket, the locking mechanism comprising:
a shell connected to the bracket, and
a lock component connected to the shell,
wherein the lock component comprises a handle, a pin, a lever, a torsion spring, and a compression spring, the handle is rotatably connected to the shell and the handle rotates between an inner position and an outer position relative to the shell, the lever is configured for latching the handle, the pin is movably connected to the shell and the pin extends out of the shell or retracts into the shell,
when the handle is located on the inner position, the lever latches the handle, the torsion spring is compressed, the compression spring pushes the pin out of the shell, the pin is configured for inserting into the slot of the rack to lock the bracket to the rack, and
when pressing the lever to unlatch the handle, the torsion spring pushes the handle rotate to the outer position, meanwhile the handle retracts the pin into the shell to unlock the bracket from the rack, and the compression spring is compressed.

20. The server of claim 19, wherein
the pin comprises a bevel, when the handle is located on the inner position, the bevel extends out of the shell, during the mounting of the hard drive to the rack, the rack moves along the bevel to press the pin into the shell, until the pin meets the slot of the rack, the compression spring pushes the pin out of the shell and into the slot, to lock the hard drive to the rack.
